(19) United States
(12) Patent Application Publication
(10) Pub. No.: US 2021/0166982 A1
(43) Pub. Date: Jun. 3, 2021

(54) WAFER STRUCTURE, DIE FABRICATION METHOD AND CHIP

(71) Applicant: Changxin Memory Technologies, Inc., Hefei (CN)

(72) Inventor: Chia-Chi HSU, Hefei (CN)

(21) Appl. No.: 17/174,690

(22) Filed: Feb. 12, 2021

Related U.S. Application Data
(63) Continuation of application No. PCT/CN2019/103358, filed on Aug. 29, 2019.

(30) Foreign Application Priority Data
Aug. 31, 2018 (CN) 201811014495.8
Aug. 31, 2018 (CN) 201821423111.3

(51) Int. Cl. H01L 21/66; H01L 21/78

(52) U.S. Cl. CPC H01L 22/32; H01L 21/78; H01L 22/14

(57) ABSTRACT

A wafer structure, a die fabrication method and a chip are provided. The wafer structure may include a wafer body and a test pad. The wafer body may include a dicing region and a functional region, and the test pad may be in the dicing region. The dicing region may be cut off in a subsequent process, and the test pad may only be needed in the wafer testing stage for engineering analysis and thus can be removed thereafter. The wafer structure may further comprise a switch circuit provided between the test pad and a plurality of dies. By arranging the test pad in the dicing region and connected to one of the plurality of dies, a wafer test can be accomplished with the test pad without the test pads occupying large areas of the functional regions of the wafer. Thus, a wafer's effective area can be more efficiently utilized.

### CROSS-REFERENCE TO RELATED APPLICATIONS

This application is a continuation application of International Patent Application No. PCT/CN2019/103358, filed on Aug. 29, 2019, which is based on and claims priority of the Chinese Patent Application Nos. 201811014495.8 and No. 201821423111.3, both filed on Aug. 31, 2018. The above-referenced applications are incorporated herein by reference in their entirety.

### TECHNICAL FIELD

The present disclosure relates to the field of semiconductor integrated circuits (ICs) and more specifically, to a wafer structure, a die fabrication method and a chip.

### BACKGROUND

In the wafer fabrication process, a wafer needs to be tested to verify its electrical properties, and the test is usually accomplished by using probes to contact test pads on the wafer. As the size of a chip continuously decreases, the size of the test pads, however, may not be correspondingly reduced since a test pad needs to provide sufficient contact area to ensure reliable contact with the probe. Therefore, for wafer testing purpose, an increasingly large portion of wafer surface may be occupied by the test pads in a chip fabrication process, which unnecessarily increases the size of a chip and reduces the usable area of a wafer. All of these may impede the miniaturization of the chip.

It is to be noted that the above information disclosed in this Background section is only for enhancement of understanding of the background of the invention and therefore may contain information that does not form the prior art that is already known to a person of ordinary skill in the art.

### SUMMARY

In view of the limitations of conventional technologies described above, this disclosure provides a wafer structure, a die fabrication method and a chip that address at least some of the aforementioned limitations.

One aspect of this disclosure may be directed to a wafer structure. The wafer structure may comprise a wafer body comprising a dicing region and a functional region, and a test pad in the dicing region. The dicing region may be configured to be cut off from the wafer body. The test pad may be located on a topmost layer of the wafer body and connected to an internal voltage source.

In some embodiments, the wafer structure may further comprise a plurality of dies located in the functional region and a switch circuit provided between the test pad and the plurality of dies. The test pad may be connected to one of the plurality of dies selected by the switch circuit.

In some embodiments, the wafer structure may be configured to be tested by connecting the test pad to a first die of the plurality of dies selected by the switch circuit.

In some embodiments, the wafer structure may be further configured to be tested by connecting the test pad to a second die of the plurality of dies selected by the switch circuit.

In some embodiments, the test pad may be connected to the plurality of dies through a connection line.

In some embodiments, the connection line may comprise a power line and a signal line. The power line may include a first end connected to the test pad and a second end connected to the plurality of dies, and may be configured to supply power for testing the plurality of dies. The signal line may include a first end connected to the test pad and a second end connected to the plurality of dies, and may be configured to transmit signals for testing the plurality of dies.

In some embodiments, the plurality of dies may further comprise a potentiometer coupled to the connection line.

In some embodiments, the aforementioned wafer structure may further include a plurality of dicing regions. The test pad may be situated in a dicing region adjacent to the plurality of dies.

In some embodiments, the wafer structure may further comprise a second test pad situated in the functional region.

In some embodiment, the aforementioned wafer structure may further comprise a plurality of test pads in the dicing region, each corresponding for testing one of a plurality of performance parameters.

In some embodiments, the plurality of test pads may be arranged in one or more rows in the dicing region.

In some embodiments, the aforementioned wafer structure may further comprise a plurality of connecting lines. Each of the plurality of test pads may be connected to the plurality of dies through one of the plurality of connecting lines.

In some embodiments, each of the plurality of connecting lines may comprise a power line and a signal line. The power line may be configured to supply power for testing the plurality of dies, and the signal line may be configured to transmit signals for testing the plurality of dies.

Another aspect of this disclosure may be directed to a die fabrication method. The method may comprise: fixing a wafer structure. The wafer structure may comprise a wafer body comprising a dicing region and a functional region, and a test pad in the dicing region. The dicing region may be configured to be cut off from the wafer body, and the test pad may be located on a topmost layer of the wafer body and connected to an internal voltage source. The method may further comprise planning a dicing path in the dicing region of the wafer structure, and dicing the wafer structure along the dicing path to obtain a die.

In some embodiments, in the aforementioned method, the wafer structure may further comprise a plurality of dies in the functional region and a switch circuit provided between the test pad and the plurality of dies. The test pad may be connected to one of the plurality of dies selected by the switch circuit. Fixing a wafer structure may further comprise connecting the test pad to one of the plurality of dies to test the wafer structure.

In some embodiments, in the aforementioned method, the wafer structure may further comprise a plurality of test pads in the dicing region, each corresponding for testing one of a plurality of performance parameters.

In some embodiments, the aforementioned method may further comprise testing the wafer structure by connecting the test pad to a first die of the plurality of dies selected by the switch circuit.

In some embodiments, the aforementioned method may further comprise testing the wafer structure by connecting the test pad to a second die of the plurality of dies selected by the switch circuit.

In some embodiments, planning a dicing path in the dicing region of the wafer structure may comprise planning the dicing path in the dicing region with the die and the test pad located on opposite sides of the dicing path.

Another aspect of this disclosure may be directed to a chip, comprising a die obtained from the die fabrication method of any of the aforementioned embodiments.

The wafer structure of this disclosure may include a dicing region and a functional region. The dicing region may be removed in a subsequent process, and the test pads may only be needed in a wafer testing stage for engineering analysis and thus may be removed without adversely affecting the performance of the die. Therefore, by arranging the test pads in the dicing region and connected to the functional region, a wafer can be tested with the test pads during a wafer testing stage, without the test pads occupying large areas of the functional region, which unnecessarily increases the size of a chip and reduces usable areas of a wafer. As a result, a wafer's effective area may be more efficiently utilized.

It should be understood that the above description and the following detailed description are exemplars and illustrations only, which do not limit the scope of this disclosure.

### BRIEF DESCRIPTION OF THE DRAWINGS

The accompanying drawings, which are incorporated in and constitute a part of the specification, illustrate embodiments in accordance with this disclosure and, together with the description, serve to explain the disclosed inventive concept. It is apparent that these drawings present only some embodiments of this inventive concept, and persons of ordinary skill in the art may obtain drawings of other embodiments from them without exerting any creative effort.

FIG. 1 is a schematic diagram illustrating a wafer structure in accordance with one embodiment of this disclosure.

FIG. 2 is a schematic diagram illustrating a wafer structure in accordance with one embodiment of this disclosure.

FIG. 3 is a flowchart illustrating a die fabrication method in accordance with one embodiment of this disclosure.

### NUMERALS IN THE DRAWINGS

100: a functional region;
200: a dicing region;
300: a test pad;
400: a potentiometer; and
500: a dicing path.

### DETAILED DESCRIPTION OF THE EMBODIMENTS

An exemplary embodiment will now be described more comprehensively with reference to the accompanying drawings. However, the exemplary embodiment can be implemented in many forms and should not be construed as being limited to those set forth herein. Rather, the embodiment is presented to provide a full and thorough understanding of the present invention and to fully convey the concepts of the exemplary embodiment to others skilled in the art. In the drawings, like reference numerals indicate the same or analogous elements, and duplicate detailed description thereof will thus be omitted.

Although relative terms like “upper” and “lower” may be used herein to describe a spatial relationship of one component to another in a device shown in the figures, they are used merely for the purpose of easy description based on, for example, the exemplary orientation depicted in the figures. It is to be understood that if the illustrated device is turned upside down, then the component described as being “upper” will now be a “lower” component. When a certain structure is described as being “on” another structure, it is possible that the specific structure is either integrally formed on the other structure or disposed thereon “directly” or “indirectly” via an intermediate structure.

As used herein, the terms “a”, “an” “the”, “said” and “at least one” are intended to mean that there are one or more elements/components/etc. As used herein, the terms “comprising” and “having” are intended to be used in an open sense to mean that there are possibly other element(s)/component(s)/etc. apart from the listed element(s)/component(s)/etc. The terms “first”, “second”, “third”, etc. as used herein are meant as labels rather than place a quantitative limitation upon the amount of the mentioned items.

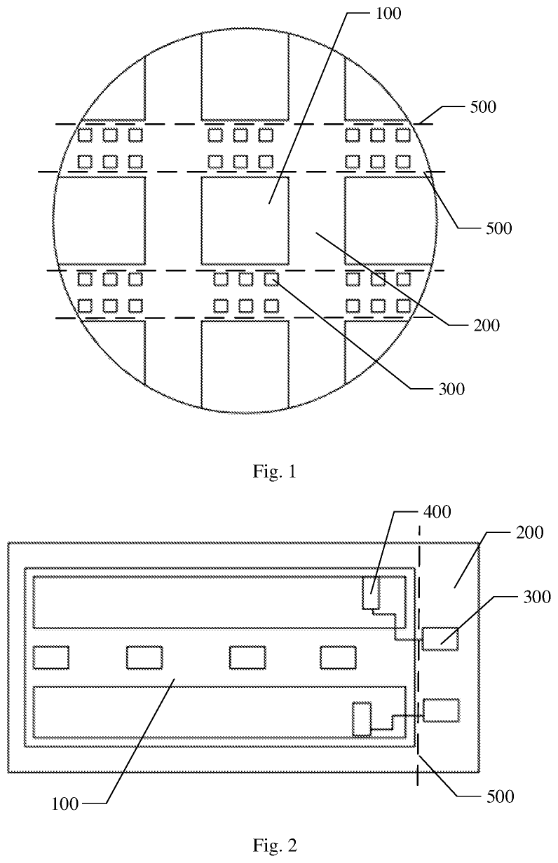

FIG. 1 is a schematic diagram illustrating a wafer structure in accordance with one embodiment of this disclosure. Referring to FIG. 1, the wafer structure may include a wafer body and a test pad 300.

The wafer body may include a dicing region 200 and a functional region 100. The dicing region 200 may be configured to be cut off from the wafer body in a later stage. The test pad 300 may be situated within the dicing region 200 and connected to the functional region 100. The test pad 300 may be configured for testing the wafer body.

In some embodiments, the wafer body may include a plurality of dicing regions 200, which may cross each other horizontally and vertically in the wafer body. The plurality of dicing regions 200 which cross each other horizontally and vertically may divide the wafer body into a plurality of functional regions 100. Each of the functional regions 100 may be connected to a corresponding test pad 300.

The wafer structure according to the embodiment of this disclosure may include a plurality of dicing regions 200 and a plurality of functional regions 100. The dicing regions 200 may be cut off in a subsequent process, and the test pads 300 may only be needed in a wafer testing stage for engineering analysis. For example, an internal voltage source of a die may usually be connected to a test pad located on a topmost layer in the wafer for the engineering analysis during a wafer testing. By arranging the test pads 300 in the dicing regions 200 and connected to the functional regions 100, a wafer can be properly tested with the test pads 300 during a wafer testing stage, without the test pads 300 occupying large areas of the functional regions 100, which impedes the miniaturization of a chip. As a result, a wafer's effective area may be more efficiently utilized. In addition, with the test pads 300 arranged in the dicing regions 200, probes for wafer testing will be deployed in the dicing regions only, which avoids the issue of an probe piercing a test pad 300 and damaging the underlying functional region 100 during a test, which otherwise may happen if the test pads 300 are arranged in the functional regions 100.

The wafer structure according to the embodiment of this disclosure will be described in a details below.

FIG. 2 is a schematic diagram illustrating a wafer structure in accordance with one embodiment of this disclosure. Referring to FIG. 2, a functional region 100 may include a plurality of dies which may be connected to the test pads 300. In general, a wafer body may be divided into a plurality of functional regions 100 by the dicing regions 200, and each of the functional regions 100 may be subsequently diced into an individual die.

Each of the dies may be connected to corresponding test pads 300. During a wafer testing, the electrical properties of each die may be tested, and the test may be done by using a probe of a tester to contact the corresponding test pads 200. Dies that fail to pass the test may be marked and discarded in a subsequent process to ensure a high production yield.

In actual applications, test pads 300 corresponding to a die may be disposed in a dicing region 200 adjacent to the die so that the electrical properties of the die can be tested. Alternatively, several dies may share a common test pad 300 and be tested separately for their electrical properties. For example, two dies located on both sides of a dicing region 200 may share common test pads 300 arranged in this dicing region 200. In a test, the die on one side of the dicing region 200 may be first tested and may be marked if its electrical properties are found unsatisfactory. Subsequently, the die on the other side of the dicing region 200 may be tested and, similarly, may be marked if its electrical properties are found unsatisfactory.

In the case of one test pad 300 is connected to a plurality of dies, a switching circuit or device may be provided between the test pad 300 and the plurality of dies. Through the switching circuit or device, the test pad 300 may be sequentially connected to different die of the plurality of dies during a test to test the electrical properties thereof. Apparently, each of the test pads 300 may also be connected to only one single die. The disclosure is not limited in this regard.

In one example, the dies to be tested may be numbered to be distinguished from one another, which facilitates the marking of the dies with undesirable electrical properties. In a wafer structure, if the dicing regions 200 partition the wafer body into separate individual dies, then the dies may be numbered according to a predetermined rule. For example, the ides may be numbered column-wise or row-wise. If the dicing regions 200 partition functional regions of the wafer body into a plurality of functional sub-regions, these functional sub-regions may also be numbered. For example, if there are four functional sub-regions, they can be numbered as A, B, C and D, respectively. If each of the functional sub-regions contains four dies, then these dies may be numbered as A1, A2, A3, A4; B1, B2, B3, B4; C1, C2, C3, C4; D1, D2, D3, D4. If any of these dies is tested to have unsatisfactory electrical properties, its number may be recorded.

Sharing of a test pad 300 across multiple dies may reduce the number of test pads 300 needed and may facilitate their arrangement in the dicing regions 200. Additionally, most, if not all, of the test pads 300 may be placed in the dicing regions 200 to facilitate the miniaturization of a chip.

The test pads 300 may be connected to the dies through a connection line configured to supply required currents and testing signals. In order to prevent crosstalk interference between the currents and testing signals, the connection line may be separated into a power line and a signal line.

The power line may have a first end connected to the test pads 300 and a second end connected to the plurality of dies, and the power line may be configured to supply power for testing the plurality of dies. The signal line may have a first end connected to the test pads 300 and a second end connected to the plurality of dies, and the signal line may be configured to transmit signals for testing the plurality of dies.

It is to be noted that if each die is to be tested for a plurality of performance parameters, then each die can be connected to a corresponding number of test pads 300, and the embodiment of this disclosure is not limited in this regard. In this case, for example, there may be a plurality of signal lines respectively connected to the corresponding test pads 300 and there may be a plurality of power lines respectively connected to the corresponding test pads 300.

In some embodiments, the dies and the test pads 300 may be wired in the following manner.

The test pads 300 may also be numbered the same way for numbering the dies, as described above. For example, the test pads 300 may be numbered correspondingly as P1, P2, P3, P4. In this case, a die A1 may be connected through a connection line to a test pad P1, a die A2 may be connected to a test pad P2, a die A3 may be connected to a test pad P3, and a die A4 may be connected to a test pad P4. Likewise, the remaining dies may also be connected to corresponding test pads 300 in a similar way.

In a test, signals detectable by the probes may include the numbers of the test pads 300 and the electrical properties of the dies corresponding to the test pads 300. The tester may determine whether the electrical properties of each die are satisfactory based on the signals from the probes and mark any die with unsatisfactory electrical properties.

Additionally, the dies may include a potentiometer 400 coupled to the connection line. Apparently, in actual applications, other components may also be disposed between the dies and test pads 300, and this disclosure is not limited in this regard.

In some embodiments, depending on number of test pads 300 needed in a wafer test, some or all of the test pads 300 may be arranged in the dicing regions 200. It is to be noted that, apart from the test pads 300, other pads may be arrange on the dies. Therefore, when arranging the pads, the pads that are needed only by wafer testing and not by any subsequent process (and therefore may be removed without affecting the dies) may be arranged in the dicing regions 200. Such arrangement may more efficiently utilize the wafer's effective area without affecting functionalities of the dies after those pads are removed.

For ease of wiring, the test pad 300 may be situated in a dicing region 200 adjacent to a die corresponding to the test pad. Apparently, in actual applications, if there is no sufficient space in the adjacent dicing region 200 for accommodating all of the test pads 300, the test pads 300 may also be arranged in other non-functional region of the wafer. This disclosure is not limited in this regard.

The plurality of test pads 300 may be arranged in an array in the dicing region 200. In each of the dicing regions 200, the test pads 300 may be arranged in one or more rows. For example, as shown in FIG. 1, when dies on opposite sides of a dicing region 200 are provided with individual test pads 300, the test pads 300 in the dicing regions 200 may be arranged into two rows. Apparently, in actual applications, the test pads 300 may also be arranged into one row or more than two rows.

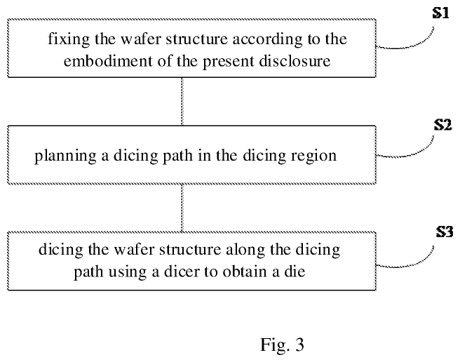

This disclosure further provides a die fabrication method. FIG. 3 is a flowchart illustrating a die fabrication method in accordance with one embodiment of this disclosure. Referring to FIG. 3, the die fabrication method may include the steps of S1 through S3.

In step S1, a wafer structure according to one of the embodiments of this disclosure may be fixed.

In step S2, a dicing path may be planned in the dicing region of the wafer structure.

In step S3, the wafer structure may be diced along the dicing path to obtain a die.

The die obtained from the die fabrication method according to this embodiment of this disclosure may not contain any redundant test pad 300, resulting in an increased utilization rate of the wafer's effective area, which facilitates the miniaturization of a chip.

In step S1, the wafer structure according to one embodiment of this disclosure may be fixed.

The wafer structure according to one embodiment of this disclosure may include a wafer body and a test pad 300. The wafer body may include a dicing region 200 and a functional region 100. The test pad 300 may be disposed in the dicing region 200 and connected to the functional region 100. The test pad 300 may be configured for testing the wafer body. In some embodiments, the wafer body may be fixed on a wafer dicer with a side of the wafer body provided with the test pad 300 facing upward.

In step S2, the dicing path may be planned in the dicing region of the wafer structure.

In order to separate the die from the test pad 300 when dicing along the dicing path 500, the dicing path 500 may be planned between the die and the test pad 300. In some embodiments, the die and the test pad 300 may be located on opposite sides of the dicing path 500.

Referring back to FIG. 1, if there are dies on both sides of a dicing region 200, two dicing paths 500 may be planned in the dicing region 200 to separate these dies arranged on both sides of the dicing region 200 from the test pad 300. For the ease of dicing, the dicing path 500 may be a straight line. In actual applications, the dicing path 500 may also be a curve line to meet certain requirements. This disclosure is not limited in this regard. When arranging the test pads 300 in the dicing region 200, the test pads 300 may be arranged according to a prescribed rule based on the dicing requirement so as to simplify the dicing paths 500 and dicing.

In step S3, the wafer may be diced along the dicing path using a dicer to obtaining a die.

During the dicing, for a dicing region 200 with dies on only one side thereof, as shown in FIG. 2, only one dicing path 500 may be needed in the dicing region 200 and the dies may be separated from the dicing region 200 as well as from any test pad 300 in the dicing region 200 within a single dicing operation. In FIG. 1, there are dies on both sides of the dicing region 200, two planned dicing paths 500 may be needed in the dicing region 200, as discussed above. One of the dicing paths may be closer to dies on one side of the dicing region 200, and the other may be closer to dies on the other side of the dicing region 200. In this case, a dicing operation may be performed first along the first dicing path, and a second dicing operation may be performed along the second dicing path, so that the dies on both sides of the dicing region 200 can be separated.

The wafer may be diced using a wire or a laser. Apparently, in actual applications, a wafer may also be diced in any other suitable manner, and this disclosure is not limited in this regard.

This disclosure further provides a chip comprising a die obtained from the die fabrication method according to any of the aforementioned embodiments of the present disclosure. The chip according to the embodiments of the present disclosure may further include pins, capacitors, resistors and other components, which are all known to those skilled in the art and will thus not be described in further details herein.

Other embodiments of the present disclosure will be apparent to those skilled in the art from considering the specification and practicing the invention disclosed herein. Accordingly, this disclosure is intended to cover all and any variations, uses, or adaptations of the disclosure which follow, in general, the principles thereof and include such departures from the present disclosure as come within common knowledge or customary practice within the art to which the invention pertains. It is also intended that the specification and examples be considered as exemplary only, with true scope and spirit of the disclosure being indicated by the appended claims.

What is claimed is:

1. A wafer structure, comprising:
a wafer body comprising a dicing region and a functional region, the dicing region configured to be cut off from the wafer body;
a test pad in the dicing region, wherein the test pad is located on a topmost layer of the wafer body and connected to an internal voltage source;
a plurality of dies located in the functional region; and
a switch circuit provided between the test pad and the plurality of dies, wherein the test pad is connected to one of the plurality of dies selected by the switch circuit.

2. The wafer structure of claim 1, wherein the wafer structure is configured to be tested by connecting the test pad to a first die of the plurality of dies selected by the switch circuit.

3. The wafer structure of claim 2, wherein wafer structure is further configured to be tested by connecting the test pad to a second die of the plurality of dies selected by the switch circuit.

4. The wafer structure of claim 1, wherein the test pad is connected to the plurality of dies through a connection line.

5. The wafer structure of claim 4, wherein the connection line comprises:
a power line comprising a first end connected to the test pad and a second end connected to the plurality of dies, the power line configured to supply power for testing the plurality of dies; and
a signal line comprising a first end connected to the test pad and a second end connected to the plurality of dies, the signal line configured to transmit signals for testing the plurality of dies.

6. The wafer structure of claim 4, wherein the plurality of dies further comprise a potentiometer coupled to the connection line.

7. The wafer structure of claim 2, further comprising a plurality of dicing regions, and wherein the test pad is situated in a dicing region adjacent to the plurality of dies.

8. The wafer structure of claim 1, further comprising a second test pad situated in the functional region.

9. The wafer structure of claim 1, further comprising:
a plurality of test pads in the dicing region, each corresponding for testing one of a plurality of performance parameters.

10. The wafer structure of claim 9, wherein the plurality of test pads are arranged in one or more rows in the dicing region.

11. The wafer structure of claim 9, further comprising:
a plurality of connecting lines, wherein each of the plurality of test pads is connected to the plurality of dies through one of the plurality of connecting lines.

12. The wafer structure of claim 11, wherein each of the plurality of connecting lines comprises a power line and a signal line, the power line configured to supply power for testing the plurality of dies, and the signal line configured to transmit signals for testing the plurality of dies.

13. A die fabrication method, comprising:
fixing a wafer structure, wherein the wafer structure comprises:
a wafer body comprising a dicing region and a functional region, the dicing region configured to be cut off from the wafer body; and
a test pad in the dicing region, wherein the test pad is located on a topmost layer of the wafer body and connected to an internal voltage source;
planning a dicing path in the dicing region of the wafer structure; and
dicing the wafer structure along the dicing path to obtain a die.

14. The method of claim 13, wherein the wafer structure further comprises:
a plurality of dies in the functional region; and
a switch circuit provided between the test pad and the plurality of dies, wherein the test pad is connected to one of the plurality of dies selected by the switch circuit,
and wherein the fixing a wafer structure further comprising:
connecting the test pad to one of the plurality of dies to test the wafer structure.

15. The method of claim 13, wherein the wafer structure further comprises:
a plurality of test pads in the dicing region, each corresponding for testing one of a plurality of performance parameters.

16. The method of claim 15, further comprising:
testing the wafer structure by connecting the test pad to a first die of the plurality of dies selected by the switch circuit.

17. The method of claim 16, further comprising:
testing the wafer structure by connecting the test pad to a second die of the plurality of dies selected by the switch circuit.

18. The method of claim 13, wherein planning a dicing path in the dicing region of the wafer structure comprises:
planning the dicing path in the dicing region with the die and the test pad located on opposite sides of the dicing path.

19. A chip, comprising a die obtained from the die fabrication method of claim 13.
